(19) United States
(12) Patent Application Publication
(10) Pub. No.: US 2012/0199193 A1
(43) Pub. Date: Aug. 9, 2012

(54) AMORPHOUS SILICON SOLAR CELL MODULE

(75) Inventors: Koichi Nishijima, Ichihara-shi (JP); Norihiko Sato, Ichihara-shi (JP)

(73) Assignee: DU PONT-MITSUI POLYCHEMICALS CO., LTD., Minato-ku, Tokyo (JP)

(21) Appl. No.: 13/500,213

(22) PCT Filed: Nov. 10, 2010
(86) PCT No.: PCT/JP2010/070044

§ 371 Date: Apr. 4, 2012

(30) Foreign Application Priority Data
Nov. 13, 2009 (JP) 2009-260131

(51) Int. Cl. H01L 31/0203; H01L 31/0376

(52) U.S. Cl. 136/258; 136/259

(57) ABSTRACT

Provided is an amorphous silicon solar cell module including a solar cell encapsulant containing a metal deactivator and silane-modified polyethylene, and a metal material adjacent to the solar cell encapsulant and having at least one selected from copper, a lead-free solder alloy and a silver film.

### TECHNICAL FIELD

The present invention relates to an amorphous silicon solar cell module including a solar cell encapsulant.

### BACKGROUND ART

Hydroelectric power generation, wind power generation, photovoltaic power generation and the like, which can be used to attempt to reduce carbon dioxide or improve other environmental problems by using inexhaustible natural energy, have received much attention. Among these, photovoltaic systems has seen a remarkable improvement in performance such as the power generation efficiency of solar cell modules, and an ongoing decrease in price, and national and local governments have worked on projects to promote the introduction of residential photovoltaic power generation systems. Thus, in recent years, the spread of photovoltaic power generation systems has advanced considerably.

By using photovoltaic power generation system, solar light energy is converted directly to electric energy using a semiconductor (solar cell element) such as a silicon cell. The performance of the solar cell element utilized there is deteriorated by contacting the outside air. Consequently, the solar cell element is sandwiched by an encapsulant or a protective film for providing buffering and prevention of contamination with a foreign substance or penetration of moisture.

For a sheet to be used as an encapsulant, a cross-linked ethylene/vinyl acetate copolymer, whose vinyl acetate content is from 25% to 33% by mass, is generally used from viewpoints of transparency, flexibility, processability, and durability (for example, see Japanese Patent Publication No. 62-14111). Meanwhile, in case the vinyl acetate content of an ethylene/vinyl acetate copolymer becomes higher, higher becomes the moisture permeability thereof In case the moisture permeability becomes higher, depending on the type or the adhesion condition of an upper transparent protective material or an underside surface protective material (so-called a back sheet), the adhesive property between the ethylene/vinyl acetate copolymer and the upper transparent protective material or the underside surface protective material may be deteriorated. Therefore, a back sheet having high barrier is utilized and a butyl rubber having high barrier is utilized to seal the circumference of a module aiming for preventing moisture.

Therefore, as a method to give adhesiveness with glass, metal, or plastic used in an upper transparent protection material or an underside surface protection material to a resin which is one of materials of an encapsulant layer responsible for a sealing function, an introduction of a silane compound to the resin has been adopted.

Generally, as the polymerization method, there are two methods of copolymerization and graft polymerization. Copolymerization is a method in which a monomer, a catalyst and an unsaturated silane compound are mixed, and polymerization is carried out at predetermined temperature and pressure. Graft polymerization is a method in which a polymer, a free radical generator and an unsaturated silane compound are mixed and stirred at a predetermined temperature to graft a silane compound into a polymer main chain or side chain. A solar cell module using an encapsulant for a solar cell made of the thus synthesized silane-modified polyethylene has also been suggested (for example, see Japanese Patent Application Laid-Open (JP-A) No. 2005-19975).

Meanwhile, as a currently available solar cell module, a crystalline silicon-based solar cell module becomes the main stream. However, the crystalline silicon-based solar cell module has problems associated with supply quantity of crystalline silicon or quality such as high purity, and therefore suffers from difficulty in reduction of module costs and a great obstacle to the propagation thereof. On the other hand, an amorphous silicon solar cell module, which is one of thin-film solar cells, is attracting attention in terms of feasibility of the reduction of module cost. The amorphous silicon solar cell module has a cell thickness which is about 1/100 of a cell thickness of a crystalline silicon-based solar cell module, while using silicon as a raw material, similar to the crystalline silicon-based solar cell module. For this reason, the amorphous silicon solar cell module has a possibility of great cost reduction.

This amorphous silicon solar cell module has a feature capable of achieving thickness reduction into a thin film.

The configuration of a cell (solar cell element) of this amorphous silicon solar cell module is significantly different from the configuration of a cell of a crystalline silicon-based solar cell module, in that the amorphous silicon solar cell module is minute and fine in terms of cell configuration thereof, as compared to a crystalline silicon-based solar cell module, and employs a thin-film electrode.

In an amorphous silicon solar cell module, a transparent electrode made of a tin oxide or the like is generally used as an electrode at the side of a cell light-receiving surface. Further, in an amorphous silicon solar cell module, a thin silver film is used as an underside surface electrode. Such an electrode has a problem of vulnerability to moisture.

Due to this problem, an encapsulant is used for encapsulating an electrode or the like. Performance of an encapsulant used in an amorphous silicon solar cell module is required to have lower moisture permeability than an encapsulant of a crystalline silicon-based solar cell module.

The silane-modified polyethylene exhibits lower moisture permeability as compared to a cross-linked product of an ethylene-vinyl acetate copolymer, and consequently is a material which is advantageous as an encapsulant of an amorphous silicon solar cell module.

However, from the experience that polyethylene has been used as a coating material of high-voltage power cables, continuous carrying of high-voltage current under high temperature environment is known to result in degradation of polyethylene. In order to prevent the degradation of polyethylene, a method of adding a metal deactivator has been proposed (for example, see JP-A No. 2001-200085).

Further, similar to high-voltage power cables, the degradation of a resin that constitutes the encapsulant, in a solar cell encapsulant, may be exhibited due to the influence of metals. In order to avoid degradation of the resin, a method of adding a metal deactivator has been proposed (for example, see JP-A No. 7-283427 and Pamphlet of International Publication No. 2006/093936).

### DISCLOSURE OF INVENTION

### Problem to be Solved by the Invention

However, an encapsulant using silane-modified polyethylene exhibits a tendency of more accelerating the corrosion of a metal material that constitutes a solar cell module, particularly the corrosion of silver (Ag) used as an electrode material, or the corrosion of a non-lead-containing solder alloy (hereinafter, also referred to as “lead-free solder alloy”) or copper (copper wire, etc.) used as a wiring material, when compared with other materials. Further, accelerated corrosion of a metal material may result in a risk of unstable power generation efficiency of a solar cell module or a risk of significant decrease in power generation efficiency of a solar cell module.

The present invention has been made in view of such circumstances. Under such circumstances, there is a need for a high-durability amorphous silicon solar cell module which is excellent in corrosion resistance of a metal material such as an electrode material or a wiring material and which achieves the prevention of quality degradation such as lowering of the power output, during long-term outdoor use. Further, there is also a need for an amorphous silicon solar cell module which has excellent adhesiveness between an encapsulant and an upper transparent protection material and/or an underside surface protection material.

### Means for Solving the Problem

The present invention has been completed based on the following finding. That is, when the silane-modified polyethylene is incorporated into an encapsulant for encapsulating a metal material (wiring, electrode, etc.) having at least one selected from copper, a lead-free solder alloy and a silver film, metal corrosion is accelerated. In terms of preventing accelerated corrosion of metal materials, an anticorrosive effect may be expected from the metal deactivator which has been conventionally used to prevent the degradation of resins.

Specific means for achieving the objects described above are as follows.

<1> An amorphous silicon solar cell module including a solar cell encapsulant containing a metal deactivator and silane-modified polyethylene, and a metal material adjacent to the solar cell encapsulant and having at least one selected from copper, a lead-free solder alloy or a silver film.

<2> The amorphous silicon solar cell module as described in <1>, wherein the metal deactivator is at least one selected from the group consisting of a hydrazine derivative and a triazole derivative, and the content of the metal deactivator in the solar cell encapsulant is 500 ppm or more.

<3> The amorphous silicon solar cell module as described in <1> or <2>, wherein the solar cell encapsulant further contains non-modified polyethylene, and a proportion of the silane-modified polyethylene is in a range of from 1% to 80% by mass, in terms of a mass ratio relative to the total mass of a mixture of the silane-modified polyethylene and the non-modified polyethylene.

<4> The amorphous silicon solar cell module as described in any one of the above <1> to <3>, wherein the content of silicon (Si) in the solar cell encapsulant is in a range of from 8 ppm to 3500 ppm in terms of an amount of polymerized silicon.

<5> The amorphous silicon solar cell module as described in any one of the above <1> to <4>, wherein the polyethylene that forms the silane-modified polyethylene is at least one selected from the group consisting of low density polyethylene, medium density polyethylene, high density polyethylene, very low density polyethylene, ultra-low density polyethylene, and linear low density polyethylene.

<6> The amorphous silicon solar cell module as described in any one of the above <1> to <5>, wherein the metal material is at least one of a busbar or an interconnector.

<7> The amorphous silicon solar cell module according to as described in any one of the above <1> to <6>, wherein the solar cell encapsulant contains at least one selected from the group consisting of an antioxidant, an ultraviolet absorber and a light stabilizer.

### Effect of the Invention

According to the present invention, there may be provided a high-durability amorphous silicon solar cell module which is excellent in corrosion resistance of a metal material such as an electrode material or an wiring material and which achieves the prevention of quality degradation such as lowering of the power output, during long-term outdoor use.

Further, according to the present invention, there may also be provided an amorphous silicon solar cell module which has excellent adhesiveness between an encapsulant and an upper transparent protection material and/or an underside surface protection material.

### BEST MODE FOR CARRYING OUT THE INVENTION

Hereinafter, the amorphous silicon solar cell module of the present invention will be described in more detail.

The amorphous silicon solar cell module of the present invention includes a solar cell encapsulant containing a metal deactivator and silane-modified polyethylene, and a metal material adjacent to the solar cell encapsulant and having at least one selected from copper, a lead-free solder alloy and a silver film.

As the metal deactivator in accordance with the present invention, a well known compound inhibiting metal-induced damage of a thermoplastic resin may be used. The metal deactivators may be used in a combination of two or more thereof

Preferred examples of the metal deactivator include a hydrazide derivative and a triazole derivative.

Specific examples of the hydrazide derivative include decamethylene dicarboxyl disalicyloyl hydrazide, 2′,3-bis[3-[3,5-di-tert-butyl-4-hydroxyphenyl]propionyl]propionohydrazide, and bis(2-phenoxypropionylhydrazide)isophthalate. Specific examples of the triazole derivative preferably include 3-(N-salicyloyl)amino-1,2,4-triazole. In addition to the hydrazide derivative and the triazole derivative, other examples of the metal deactivator include 2,2′-dihydroxy-3,3′-di(a-methylcyclohexyl)-5,5′-dimethyl.diphenylmethane, tris(2-methyl-4-hydroxy-5-tert-butylphenyl)butane, and a mixture of 2-mercaptobenzimidazole and phenol condensate.

In addition, as the hydrazide derivative, decamethylene dicarboxyl disalicyloyl hydrazide is commercially available under the product name of ADK STAB CDA-6 (manufactured by ADEKA), and 2′,3-bis[3-[3,5-di-tert-butyl-4-hydroxyphenyl]propionyl]propionohydrazide is commercially available under the product name of IRGANOX MD1024 (manufactured by Ciba Specialty Chemicals K.K. Japan, currently BASF Japan).

As the triazole derivative, 3-(N-salicyloyl)amino-1,2,4-triazole is commercially available under the product names of ADK STAB CDA-1 and CDA-1M (all manufactured by ADEKA).

The content of the metal deactivator in the solar cell encapsulant is preferably 500 ppm or more, and more preferably 1000 ppm or more.

If the content of the metal deactivator is within the above-specified range, corrosion and corrosion-induced lowering of the power output may be inhibited more effectively.

The upper limit of the content of the metal deactivator in the solar cell encapsulant is preferably 20000 ppm, and more preferably 5000 ppm. This range of the metal deactivator content may achieve a further reduction of costs while preferably maintaining anticorrosive effects.

In the present specification, the unit of content, “ppm” is by mass.

In an amorphous silicon solar cell module, a wiring or electrode, or the like known as a busbar or interconnector is formed as a metal material adjacent to a solar cell encapsulant. The busbar or the interconnector is used in a module, for the purpose of providing adhesion between cells (solar cell elements) or collecting generated electricity. The busbar or interconnector generally employs a copper wire coated with a solder alloy. Taking into consideration an influence on the environment, a lead-free solder alloy (non-lead-containing solder alloy) is used increasingly in place of a lead-containing solder alloy. In particular, by the EU's RoHS(Restriction of Hazardous Substances), the use of a lead-containing solder alloy is restricted, use of a lead-free solder alloy becomes popular.

However, a wiring material or electrode material such as busbar or interconnector using a lead-free solder alloy has a problem that by flow of a melted solder alloy, in terms of a structure of the wiring material or electrode material, the copper occasionally appears on the surface and is corroded correspondingly. For this reason, when being combined with an encapsulant using silane-modified polyethylene, a busbar or interconnector is readily susceptible to corrosion.

Here, the lead-free solder alloy includes tin (Sn) as a main component. Examples of the lead-free solder alloy include the following alloys.
An alloy consisting of tin, silver and copper (SnAgCu-based)
An alloy consisting of tin and bismuth (SnBi-based)
An alloy consisting of tin, zinc and bismuth (SnZnBi-based)
An alloy consisting of tin and copper (SnCu-based)
An alloy consisting of tin, silver, indium and bismuth (SnAgInBi-based)
An alloy consisting of tin, zinc and aluminum (SnZnAl-based)

The present invention may use any type of these alloys.

The silane-modified polyethylene used in the solar cell encapsulant in accordance with the present invention has a problem of accelerating corrosion of silver even when being brought into contact with, for example, a thin silver film used as an underside surface electrode.

As used herein, the term “underside surface electrode” refers to a metal electrode which, in an amorphous silicon solar cell module, is provided on an underside surface (a surface of the side opposite to a surface of the side where sunlight is entered (front surface)) of an amorphous silicon solar cell element and is adjacent to a solar cell encapsulant.

Hereinafter, the silane-modified polyethylene of the present invention will be described in more detail.

The solar cell encapsulant in accordance with the present invention contains, as a main component, at least one of silane-modified polyethylenes obtained by the reaction of an ethylenically unsaturated silane compound with polyethylene using a crosslinking agent.

In the preparation of silane-modified polyethylene, polyethylene for polymerization, being used for graft polymerization of an ethylenically unsaturated silane compound, is not particularly limited as long as it is a polymer which is generally commercially available as polyethylene. Specific examples of the polyethylene include low density polyethylene, medium density polyethylene, high density polyethylene, very low density polyethylene, and ultra-low density polyethylene. These structures may be branched or linear.

These various polyethylenes may be used in a combination of two or more thereof

The polyethylene for graft polymerization is preferably a polyethylene having many side chains. Generally, polyethylene having many side chains has a low density, whereas polyethylene having few side chains has a high density. Therefore, it can be said that a polyethylene having a low density is preferable. The density of polyethylene for graft polymerization in accordance with the present invention is preferably in the range of from 0.850 to 0.960g/cm³, and more preferably from 0.865 to 0.930g/cm³. This is because if the polyethylene is a polyethylene having many side chains, that is, polyethylene having a low density, graft polymerization of an ethylenically unsaturated silane compound into polyethylene becomes easy.

The ethylenically unsaturated silane compound is not particularly limited as long as it is graft-polymerizable with the polyethylene.

For example, the ethylenically unsaturated silane compound may be at least one selected from the group consisting of vinyltrimethoxysilane, vinyltriethoxysilane, vinyltripropoxysilane, vinyltriisopropoxysilane, vinyltributoxysilane, vinyltripentyloxysilane, vinyltriphenoxysilane, vinyltribenzyloxysilane, vinyltrimethylenedioxysilane, vinyltriethylenedioxysilane, vinylpropionyloxysilane, vinyltriacetoxysilane, and vinyltricarboxysilane. Among these, vinyltrimethoxysilane is preferably used in the present invention.

In the present invention, the content of the ethylenically unsaturated silane compound in the solar cell encapsulant containing silane-modified polyethylene is preferably 10 ppm or more, and more preferably 20 ppm or more. When the content of the ethylenically unsaturated silane compound is within the above-specified range, there is provided strong adhesion with the material used in an upper transparent protection material and an underside surface protection material to be described hereinafter, for example glass and the like. In addition, the upper limit of the content of the ethylenically unsaturated silane compound is preferably 40000 ppm, and more preferably 30000 ppm. The upper limit is not limited from the viewpoint of adhesiveness with glass or the like. There is no change in adhesiveness with glass or the like even when the content of the ethylenically unsaturated silane compound is outside the above-specified range, but production costs increase.

When the content of the ethylenically unsaturated silane compound is in the range of 5000 ppm or less, an improvement of adhesiveness in response to the content of the ethylenically unsaturated silane compound is more conspicuous. Accordingly, the upper limit of the content of the ethylenically unsaturated silane compound is also preferably 5000 ppm from the viewpoint of economic efficiency or mass-produced productivity.

Further, the silane-modified polyethylene is preferably present in admixture with non-modified polyethylene for dilution in the solar cell encapsulant. At this time, the content of the silane-modified polyethylene is preferably within the range of from 1 to 80% by mass, and more preferably from 5 to 70% by mass, when the total mass of a mixture of silane-modified polyethylene and non-modified polyethylene was taken to be 100% by mass.

Also in this case, by having an ethylenically unsaturated silane compound which is polymerized with polyethylene, adhesiveness with glass or the like is imparted to silane-modified polyethylene. Therefore, since the solar cell encapsulant has the foregoing silane-modified polyethylene, a solar cell encapsulant exhibits an increase in adhesiveness with glass or the like. Accordingly, the foregoing silane-modified polyethylene is preferably used within the above-specified range, from the viewpoint of adhesiveness with glass or the like, and costs.

Based on the total mass of the solar cell encapsulant containing silane-modified polyethylene, the content of silicon (Si) in terms of the amount of polymerized silicon is in the range of from 8 ppm to 3500 ppm, particularly from 10 ppm to 3000 ppm, and preferably from 50 ppm to 2000 ppm. When the amount of polymerized silicon is within this range, adhesiveness with an upper transparent protection material or an underside surface protection material or a solar cell element may be excellently maintained and it is also advantageous from the viewpoint of costs.

In the present invention, as a method for measuring the amount of polymerized silicon, there is used a method in which only an encapsulant layer (encapsulant for solar cell) is heated and burnt to ashes, thus resulting in conversion of polymerized silicon (polymerized Si) into SiO₂, the ashes are melted in alkali and dissolved in pure water, followed by adjustment to a constant volume and quantitative analysis of polymerized Si is carried out by ICP emission spectrometry (high-frequency plasma emission spectrometer: ICPS8100, manufactured by Shimadzu Corporation).

Further, silane-modified polyethylene preferably has a melt flow rate (MFR) of from 0.5 to 10 g/10 minutes, as measured at 190° C. under a load of 2.16 kg, and more preferably from 1 to 8 g/10 minutes. If an MFR is within the above-specified range, lamination moldability of a solar cell encapsulant and adhesiveness with an upper transparent protection material and an underside surface protection material are excellent.

The melting point of silane-modified polyethylene is preferably 120° C. or lower. In the preparation of a solar cell module using a solar cell encapsulant, the melting point is preferably the above-specified range from the viewpoint of processability or the like. The measurement method of a melting point will be described hereinafter.

Examples of the crosslinking agent added to silane-modified polyethylene include organic peroxides including hydroperoxides such as dicumyl peroxide, diisopropylbenzene hydroperoxide, and 2,5-dimethyl-2,5-di(hydroperoxy)hexane; dialkyl peroxides such as di-t-butyl peroxide, t-butyl cumyl peroxide, 2,5-dimethyl-2,5-di(t-butylperoxy)hexane, and 2,5-dimethyl-2,5-di(t-peroxy)hexyne-3; diacyl peroxides such as bis-3,5,5-trimethylhexanoyl peroxide, octanoyl peroxide, benzoyl peroxide, o-methylbenzoyl peroxide, and 2,4-dichlorobenzoyl peroxide; peroxy esters such as t-butyl peroxyacetate, t-butyl peroxy-2-ethylhexanoate, t-butyl peroxypivalate, t-butyl peroxyoctoate, t-butyl peroxyisopropylcarbonate, t-butyl peroxybenzoate, di-t-butyl peroxyphthalate, 2,5-dimethyl-2,5-di(benzoylperoxy)hexane, and 2,5-dimethyl-2,5-di(benzoylperoxy)hexyne-3; ketone peroxides such as methylethylketone peroxide, and cyclohexanoneperoxide; and azo compounds such as azobisisobutyronitrile, and azobis(2,4-dimethylvaleronitrile).

The content of the crosslinking agent used is preferably 0.01% by mass or more, based on the total amount of an ethylenically unsaturated silane compound and polyethylene in the production of the silane-modified polyethylene. When the content of the crosslinking agent is 0.01% by mass or more, graft polymerization of an ethylenically unsaturated silane compound with polyethylene excellently proceeds.

In the present invention, the solar cell encapsulant is preferably a mixture having silane-modified polyethylene and non-modified polyethylene for diluting the silane-modified polyethylene. Examples of the non-modified polyethylene for dilution include polyethylene such as those exemplified as the foregoing polyethylene for polymerization being used for graft polymerization. Further, the polyethylene for dilution in accordance with the present invention is preferably a resin of the same kind as a base polymer of silane-modified polyethylene, that is, polyethylene for graft polymerization used in the production of silane-modified polyethylene.

Since silane-modified polyethylene is relatively expensive, the constitution of a solar cell encapsulant using a mixture of silane-modified polyethylene and non-modified polyethylene for dilution is advantageous in terms of costs, as compared to the constitution of a solar cell encapsulant using silane-modified polyethylene alone.

The polyethylene for dilution preferably has a melt flow rate of from 0.5 to 10 g/10 minutes at 190° C. under a load of 2.16 kg, and more preferably from 1 to 8 g/10 minutes. This is because lamination moldability or the like of a solar cell encapsulant is excellent.

The melting point of the polyethylene for dilution is preferably 130° C. or lower. The above-specified range is preferable from the viewpoint of processability or the like in the production of a solar cell module using a solar cell encapsulant.

Further, measuring the melting point of the silane-modified polyethylene and the melting point of the polyethylene for dilution is carried out by differential scanning calorimetry (DSC), according to the transition temperature measurement method of plastics (JIS K7121). Further, when there are two or more melting point peaks, a higher temperature side is taken as a melting point.

In the present invention, if necessary, additives such as an ultraviolet absorber, a light stabilizer, an antioxidant and a thermostabilizer may be used. When the solar cell encapsulant of the present invention contains the foregoing silane-modified polyethylene, and an ultraviolet absorber, a light stabilizer, an antioxidant and a thermostabilizer are added thereto, long-term stable mechanical strength, adhesive strength, prevention of yellowing, prevention of cracking, and excellent processing suitability may be obtained.

The ultraviolet absorber absorbs harmful ultraviolet rays in sunlight and converts them into harmless thermal energy in the molecule thereof, and prevents the excitation of active species of photo-deterioration initiation present in the polymers used in the silane-modified polyethylene and the polyethylene for dilution. Specifically, at least one may be used selected from the group consisting of a benzophenone-based ultraviolet absorber, a benzotriazole-based ultraviolet absorber, a salicylate-based ultraviolet absorber, an acrylnitrile-based ultraviolet absorber, a metal complex salt-based ultraviolet absorber, a hindered amine-based ultraviolet absorber, and an inorganic ultraviolet absorber such as ultrafine particulate titanium oxide (particle diameter: from 0.01 μm to 0.06 μm) or ultrafine particulate zinc oxide (particle diameter: from 0.01 μm to 0.04 μm).

Examples of the ultraviolet absorber include benzophenone-based ultraviolet absorbers such as 2-hydroxy-4-methoxybenzophenone, 2,2′-dihydroxy-4-methoxybenzophenone, 2-hydroxy-4-methoxy-2-carboxybenzophenone and 2-hydroxy-4-n-octoxybenzophenone; benzotriazole-based ultraviolet absorbers such as 2-(2′-hydroxy-3′,5′-di-t-butylphenyl)benzotriazole, 2-(2′-hydroxy-5-methylphenyl)benzotriazole and 2-(2′-hydroxy-5-t-octylphenyl)benzotriazole; and salicylate-based ultraviolet absorbers such as phenylsalicylate and p-octylphenylsalicylate.

The light stabilizer captures active species which start to deteriorate by light in the polymers used in silane-modified polyethylene and polyethylene for dilution, thereby prevents photooxygenation. Specifically, at least one selected from the group consisting of a hindered amine-based compound, a hindered piperidine-based compound, and other compounds may be used. Examples of the hindered amine-based light stabilizer include 4-acetoxy-2,2,6,6-tetramethylpiperidine, 4-stearoyloxy-2,2,6,6-tetramethylpiperidine, 4-acryloyloxy-2,2,6,6-tetramethylpiperidine, 4-benzoyloxy-2,2,6,6-tetramethylpiperidine, 4-cyclohexanoyloxy-2,2,6,6-tetramethylpiperidine, 4-(o-chlorobenzoyloxy)-2,2,6,6-tetramethylpiperidine, 4-(phenoxyacetoxy)-2,2,6,6-tetramethylpiperidine, 1,3,8-triaza-7,7,9,9-tetramethyl-2,4-dioxo-3-n-octyl-spiro[4,5]decane, bis(2,2,6,6-tetramethyl-4-piperidyl)sebacate, bis(2,2,6,6-tetramethyl-4-piperidyl)terephthalate, bis(1,2,2,6,6-pentamethyl-4-piperidyl)sebacate, tris(2,2,6,6-tetramethyl-4-piperidyl)benzene-1,3,5-tricarboxylate, tris(2,2,6,6-tetramethyl-4-piperidyl)-2-acetoxypropane-1,2,3-tricarboxylate, tris(2,2,6,6-tetramethyl-4-piperidyl)-2-hydroxypropane-1,2,3-tricarboxylate, tris(2,2,6,6-tetramethyl-4-piperidyl)triazine 2,4,6-tricarboxylate, tris(2,2,6,6-tetramethyl-4-piperidine)phosphite, tris(2,2,6,6-tetramethyl-4-piperidyl)butane-1,2,3-tricarboxylate, tetrakis(2,2,6,6-tetramethyl-4-piperidyl)propane-1,1,2,3-tetracarboxylate, and tetrakis(2,2,6,6-tetramethyl-4-piperidyl)butane-1,2,3,4-tetracarboxylate.

As the antioxidant, various hindered phenol-based antioxidants may be used. Specific examples of the hindered phenol-based antioxidant include 2,6-di-t-butyl-p-cresol, 2-t-butyl-4-methoxyphenol, 3-t-butyl-4-methoxyphenol, 2,6-di-t-butyl-4-ethylphenol, 2,2′-methylenebis(4-methyl-6-t-butylphenol), 2,2′-methylenebis(4-ethyl-6-t-butylphenol), 4,4′-methylenebis(2,6-di-t-butylphenol), 2,2′-methylenebis[6-(1-methylcyclohexyl)-p-cresol], bis[3,3-bis(4-hydroxy-3-t-butylphenyl)butyric acid]glycol ester, 4,4′-butylidenebis(6-t-butyl-m-cresol), 2,2′-ethylidenebis(4-sec-butyl-6-t-butylphenol), 2,2′-ethylidenebis(4,6-di-t-butylphenol), 1,1,3-tris(2-methyl-4-hydroxy-5-t-butylphenyl)butane, 1,3,5-tris(3,5-di-t-butyl-4-hydroxybenzyl)-2,4,6-trimethylbenzene, 2,6-diphenyl-4-octadecyloxyphenol, tetrakis[methylene-3-(3,5-di-t-butyl-4-hydroxyphenyl)propionate]methane, n-octadecyl-3-(3,5-di-t-butyl-4-hydroxyphenyl)propionate, 4,4′-thiobis(6-t-butyl-m-cresol), tocopherol, 3,9-bis[1,1-dimethyl-2-[β-(3-t-butyl-4-hydroxy-5-methylphenyl)propionyloxy]ethyl]2,4,8,10-tetraoxaspiro[5,5]undecane, and 2,4,6-tris(3,5-di-t-butyl-4-hydroxybenzylthio)-1,3,5-triazine.

Examples of the thermostabilizer include phosphorus-based stabilizers such as tris(2,4-di-tert-butylphenyl)phosphate, bis[2,4-bis(1,1-dimethylethyl)-6-methylphenyl]ethyl phosphite, tetrakis(2,4-di-tert-butylphenyl)[1,1-biphenyl]-4,4′-diylbisphosphonate, and bis(2,4-di-tert-butylphenyl)pentaerythritoldiphosphite; and lactone-based stabilizers such as reaction products of 8-hydroxy-5,7-di-tert-butyl-furan-2-one and o-xylene. These may be used alone or in a combination of two or more thereof. Among them, combined use of a phosphorus-based stabilizer and a lactone-based stabilizer is preferable.

The content of the light stabilizer, the ultraviolet absorber, the thermostabilizer or the like may vary depending on the particle shape, density or the like, but is preferably within the range of from 0.01 to 5% by mass, based on the total mass of a solar cell encapsulant.

Further, when the solar cell encapsulant is used in a solar cell module as described hereinafter, no crosslinking is the strong point of the present invention. From this point of view, it is not necessary for silane-modified polyethylene to form a crosslinking structure. Accordingly, a catalyst or the like for promoting the condensation of silanol groups is not always necessary.

Specifically, a silanol condensation catalyst for promoting the dehydrating condensation reaction between silanols of silicone, such as dibutyltin diacetate, dibutyltin dilaurate, dibutyltin dioctate or dioctyltin dilaurate, is preferably substantially not incorporated.

Further, the solar cell encapsulant may contain, if necessary, other additives such as a colorant, a light diffusing agent, and a flame retardant, in addition to the foregoing additives such as ultraviolet absorber.

Examples of the colorant include a pigment, an inorganic compound and a dye and the like. As the colorant, particularly a white colorant includes titanium oxide, zinc oxide and calcium carbonate.

Examples of the light diffusing agent include inorganic spherical materials such as glass beads, silica beads, silicon alkoxide beads, and hollow glass beads; and organic spherical materials such as acrylic or vinyl benzene-based plastic beads.

Examples of the flame retardant include a halogen-based flame retardant such as bromide, a phosphorus-based flame retardant, a silicon-based flame retardant, and a metal hydroxide such as magnesium hydroxide or aluminum hydroxide.

The shape of the solar cell encapsulant used in the present invention preferably has an elongated shape. The elongated shape referred to herein includes any shape of sheet-like and film-like shapes.

The film thickness of the solar cell encapsulant is preferably in the range of from 10 to 2000 μm, and particularly preferably from 100 to 1250 μm. When the film thickness is 10 μm or more, a cell or wiring may be sealed excellently and trapped bubbles or voids are not readily generated. When the film thickness is 2000 μm or lower, an increase in module weight is inhibited, workability during such as installation or the like becomes excellent, and it is also advantageous from the viewpoint of costs.

The melt flow rate (MFR) at 190° C. under a load of 2.16kg of silane-modified polyethylene or a mixture of silane-modified polyethylene and non-modified polyethylene for dilution, which constitutes a solar cell encapsulant as described above, is in the range of from 0.5 to 10g/10 minutes, and particularly preferably from 1 to 8g/10 minutes. In other words, if an MFR is within the above-specified range, adhesiveness with an upper transparent protection material and an underside surface protection material as well as processability of the solar cell encapsulant is more improved.

Next, a method for preparing the solar cell encapsulant of the present invention will be described.

First, an example of a method for preparing silane-modified polyethylene will be described.

Silane-modified polyethylene may be obtained by heating, melting and mixing a mixture of an ethylenically unsaturated silane compound, non-modified polyethylene and a crosslinking agent, followed by graft polymerization of the ethylenically unsaturated silane compound into polyethylene.

Although the heating, melting and mixing method of a mixture is not particularly limited, preferred is a method in which with regard to additives, the additives and polyethylene are melted and kneaded in advance using an extruder to prepare a master batch with incorporation of the additives into polyethylene, the master batch is mixed in other main raw materials, and the mixture is melted and kneaded in an extruder, preferably an extruder with vent. The heating temperature is preferably 300° C. or lower, and more preferably 270° C. or lower. The silane-modified polyethylene is preferably melted and mixed in the above-specified temperature range, because the silanol group portion is readily susceptible to crosslinking and consequently gelling by heating.

Next, an example of a method of forming a solar cell encapsulant will be described.

Although the foregoing method is possible in which silane-modified polyethylene and non-modified polyethylene are heated, melted and mixed, the resulting silane-modified polyethylene is processed into pellet, and the pellet is heat-melted again and extracted, as described above, another method is also possible in which the silane-modified polyethylene and the non-modified polyethylene for dilution are mixed and introduced into a hopper of an extruder, and the mixture is heat-melted in a cylinder. The latter is superior in terms of costs.

After heating, melting and mixing of raw materials as described above, the mixture may be formed into a sheet having a thickness of from 100 to 1500 μm by a conventional method such as by a T-die or inflation. In this way, a solar cell encapsulant is prepared.

The heating temperature at the step of another heat-melting is preferably 300° C. or lower, and more preferably 270° C. or lower. As described above, since the silanol group portion is readily crosslinked and consequently gelled by heating in the silane-modified polyethylene, the resin is preferably heat-melted and extruded in the above-specified range.

Next, a solar cell module will be described.

The solar cell module of the present invention is prepared by fixing an upper part of the side of a solar cell element (cell) where sunlight enters and a lower part of the side opposite to the sunlight-incident side, by means of a protection material.

In the present specification, a protection material with transparency disposed on the upper part of a solar cell element (the side where sunlight enters) may be referred to as “upper transparent protection material”, and a protection material disposed on the lower part of a solar cell element (the side opposite to side where sunlight enters) may be referred to as “lower protection material” or “underside surface protective material”.

Examples of the constitution of the solar cell module of the present invention include:

(1) Constitution in which a solar cell element formed on a conductive glass or polyimide film by sputtering or the like is disposed such that solar cell encapsulants sandwich from both sides of the solar cell element, as in a layer structure of upper transparent protection material/solar cell encapsulant/solar cell element/solar cell encapsulant/lower protection material,

(2) Constitution in which a solar cell encapsulant and a lower protection material are formed on a solar cell element formed on the surface of an upper transparent protection material (for example, an amorphous silicon solar cell element formed on a transparent electrode of a conductive glass by sputtering or the like) (that is, a constitution in which a solar cell element is sandwiched in between an upper transparent protection material and a solar cell encapsulant, as in a layer structure of upper transparent protection material/solar cell element/solar cell encapsulant/lower protection material), and other constitutions.

In both constitutions of (1) and (2), a metal material (for example, busbar, interconnector, underside surface electrode, etc.) adjacent to a solar cell encapsulant and having at least one selected from copper, a lead-free solder alloy and a silver film is provided.

At this time, the constitution using a thin silver film as an underside surface electrode is capable of particularly exhibiting the effect of the present invention and is therefore a preferred embodiment.

The solar cell element in accordance with the present invention is an amorphous silicon-based solar cell element. This solar cell element includes not only a solar cell element having a single structure, but also a solar cell element having a tandem structure containing germanium or the like, and a solar cell element having a triple structure.

Regarding the method of preparing a solar cell module, a known method may be used.

For example, there is a lamination method in which an upper transparent protection material, a solar cell encapsulant, a solar cell element, a solar cell encapsulant, and an underside surface protection material are sequentially laminated in this order, followed by integration, vacuum suction and thermocompression. When such a lamination method is adopted, the lamination temperature is preferably in the range of from 110° C. to 180° C., and particularly preferably from 130° C. to 180° C. If the lamination temperature is 110° C. or higher, melting is achieved and therefore adhesiveness with an upper transparent protection material, an auxiliary electrode or a solar cell element, an underside surface protection material or the like is excellent. If the lamination temperature is 180° C. or lower, it is preferable because water bridges occurring due to atmospheric moisture may be further inhibited and gel fraction may be further reduced.

The lamination time is preferably in the range of from 5 to 30 minutes, and particularly preferably from 8 to 20 minutes. If the lamination time is 5 minutes or more, melting is good and therefore adhesiveness with the foregoing members becomes excellent. If the lamination time is 30 minutes or less, this contributes to decreased occurrence of problems in terms of processes, and an increase in gel fraction is inhibited particularly depending on temperature or humidity conditions. Further, although excessively high humidity results in an increased gel fraction, whereas excessively low humidity may result in a risk of decreased adhesiveness with various members, there is no particular problem as long as it is humidity under the ordinary atmospheric environment.

The solar cell encapsulant may be provided between the upper transparent protection material and the solar cell element, or may also be provided between the underside surface protection material and the solar cell element. In the solar cell module, other layers may be optionally laminated for the purpose of sunlight absorption, reinforcement, and the like.

The upper transparent protection material used in the solar cell module of the present invention is provided at the side where sunlight enters and therefore is preferably a transparent substrate. Examples of the upper transparent protection material include a glass, a fluororesin sheet, a transparent composite sheet with lamination of a weather-resistant film and a barrier film or the like may be used.

Examples of the underside surface protection material used in the solar cell module of the present invention include a metal such as aluminum, a fluororesin sheet, a composite sheet with lamination of a weather-resistant film and a barrier film or the like may be used.

### EXAMPLES

Hereinafter, the invention will be more specifically described with reference to Examples, but the invention is not intended to be limited to the following Examples, as long as the gist is maintained. Unless otherwise specifically stated, the “part” is by mass.

Although the following corrosion test is carried out using an Ag substrate (silver-plated steel plate) and an interconnector, an Ag electrode is generally used as the electrode on an underside surface of an amorphous silicon solar cell. In addition, the interconnector is one commonly used in modules. When these metal members are corroded under the environment of usage, metal oxides are produced and then electrical resistance is increased. This contributes to lowering of the power output. Therefore, in the following corrosion test, metal corrosiveness is evaluated as means for evaluating reliability of the module of the present invention. A test based on the current status of the module of the present invention may be carried out by the following corrosion test.

1. Raw Materials

The following materials were prepared as raw materials.

(A) Polymer Materials

(A-1) Ethylene·α-olefin copolymer: density=0.898g/cm³, MFR (JIS K7210-1999, 190° C., 2160g load)=3.5g/10 min, melting point=90° C. (KERNEL KF360T, manufactured by Japan Polyethylene Corporation)

(A-2) Ethylene.a-olefin copolymer: density=0.921g/cm³, MFR (JIS K7210-1999, 190° C., 2160 g load)=2.5g/l0min, melting point=108° C. (KERNEL KF283, manufactured by Japan Polyethylene Corporation)

(A-3) Ethylene-vinyl acetate copolymer: density=0.950g/cm³, MFR (JIS K7210-1999, 190° C., 2160 g load)=15 g/10min, melting point=71° C. (EVAFLEX EV250R, manufactured by Du Pont-Mitsui Polychemicals Co., Ltd.)

(A-4) Ethylene·α-olefin copolymer: density=0.903g/cm³, MFR (JIS K7210-1999, 190° C., 2160 g load)=1.2g/10min, melting point=98° C. (EVOLUE SP0511, manufactured by Mitsui Chemicals, Inc.)

—(B) Silane Coupling Agent—

(B-1) Vinyl trimethoxysilane

(B-2) 3-methacryloxypropyl trimethoxysilane

—(C) Various Additives—

(C-1-1) Phenol-based antioxidant: IRGANOX 1010 (manufactured by Ciba Specialty Chemicals K.K. Japan, currently BASF Japan Ltd.)

(C-1-2) Phenol-based antioxidant: IRGANOX 1076 (manufactured by Ciba Specialty Chemicals K.K. Japan, currently BASF Japan Ltd.)

(C-2) Phosphorus-based antioxidant: IRGAFOS 168 (manufactured by Ciba Specialty Chemicals K.K. Japan, currently BASF Japan Ltd.)

(C-3-1) Metal deactivator: ADK STAB CDA-6 (manufactured by ADEKA)

(C-3-2) Metal deactivator: ADK STAB CDA-1 (manufactured by ADEKA)

(C-3-3) Metal deactivator: ADK STAB CDA-1 M (manufactured by ADEKA)

(C-3-4) Metal deactivator: IRGANOX MD1024 (manufactured by Ciba Specialty Chemicals K.K. Japan, currently BASF Japan Ltd.)

(C-4) Ultraviolet absorber: TINUVIN 326 (manufactured by Ciba Specialty Chemicals K.K. Japan, currently BASF Japan Ltd.)

(C-5) Ultraviolet absorber: CHIMASSORB 81 (manufactured by Ciba Specialty Chemicals K.K. Japan, currently BASF Japan Ltd.)

(C-6) Light stabilizer: SANOL 770 (manufactured by Sankyo)

(C-7) Crosslinking agent: PERKMIL D (manufactured by Nof Corporation)

(C-8) Crosslinking agent: LUPEROX 101 (manufactured by Arkema Yoshitomi, Ltd.)

(C-9) Crosslinking agent: LUPEROX TBEC (manufactured by Arkema Yoshitomi, Ltd.)

—(D) Preparation of Additive Master Batch—

(D-1)

Using a twin-screw extruder (L/D=32, 30 mmφ) at a processing temperature of 150° C., 96 parts by mass of KERNEL KF283, 1.87 parts by mass of TINUVIN 326, 1.87 parts by mass of SANOL 770, and 0.5 parts by mass of IRGAFOS 168 were kneaded to prepare a master batch (D-1).

(D-2)

Using a twin-screw extruder (L/D=32, 30mmφ) at a processing temperature of 150° C., 96 parts by mass of KERNEL KF283, 1.87 parts by mass of TINUVIN 326, 1.87 parts by mass of SANOL 770, and 0.5 parts by mass of IRGANOX 1010 were kneaded to prepare a master batch (D-2).

(D-3)

Using a twin-screw extruder (L/D=32, 30mmφ) at a processing temperature of 150° C., 96 parts by mass of KERNEL KF283, 1.87 parts by mass of TINUVIN 326, 1.87 parts by mass of SANOL 770, 0.5 parts by mass of IRGANOX 1010, and 1 part by mass of ADK STAB CDA-6 were kneaded to prepare a master batch (D-3).

(D-4)

Using a twin-screw extruder (L/D=32, 30mmφ) at a processing temperature of 150° C., 96 parts by mass of EVOLUE SP0511, 1.87 parts by mass of TINUVIN 326, and 1.87 parts by mass of SANOL 770 were kneaded to prepare a master batch (D-4).

(D-5)

Using a twin-screw extruder (L/D=32, 30mmφ) at a processing temperature of 150° C., 98 parts by mass of EVOLUE SP0511, and 2 parts by mass of IRGANOX 1076 were kneaded to prepare a master batch (D-5).

(D-6)

Using a twin-screw extruder (L/D=32, 30mmφ) at a processing temperature of 150° C., 98 parts by mass of EVOLUE SP0511, and 2 parts by mass of ADK STAB CDA-6 were kneaded to prepare a master batch (D-6).

(D-7)

Using a twin-screw extruder (L/D=32, 30mmφ) at a processing temperature of 150° C., 98 parts by mass of EVOLUE SP0511, and 2 parts by mass of ADK STAB CDA-1 were kneaded to prepare a master batch (D-7).

(D-8)

Using a twin-screw extruder (L/D=32, 30mmφ) at a processing temperature of 150° C., 98 parts by mass of EVOLUE SP0511, and 2 parts by mass of ADK STAB CDA-1M were kneaded to prepare a master batch (D-8).

(D-9)

Using a twin-screw extruder (L/D=32, 30mmφ) at a processing temperature of 150° C., 98 parts by mass of EVOLUE SP0511, and 2 parts by mass of IRGANOX MD1024 were kneaded to prepare a master batch (D-9).

2. Evaluation Method

According to the following method, the evaluation was carried out for encapsulation sheets of the following Examples and Comparative Examples. The evaluation results are given in Table 1 below and Table 2 below.

As an upper transparent protection material, the following blue glass (float glass) was prepared.
Substrate

Upper transparent protection material: blue glass (float glass) (thickness=3.2mm, size=7.5cm×12cm)

(1) Substrate Adhesiveness

1-1. Glass Adhesion

Adhesion was carried out on the foregoing blue glass under the following conditions.
Adhesion conditions: 150° C.×3min×5min (Provided that for Comparative Example 2, lamination was carried out at 130° C.×3min×3min, followed by further curing at 145° C. for 40min)
Laminating apparatus: vacuum laminator (LM-50×50S manufactured by NPC Corp).
Sample composition: blue glass (float glass)/encapsulation sheet
Measurement: Adhesion between glass and encapsulation sheet was measured by cutting a sample into a 15mm width, and pulling a blue glass/encapsulation sheet end of the sample at a tensile speed of 100mm/min in the direction perpendicular to the glass surface.

(2) Corrosion Test-1

2-1. Interconnector
Interconnector (1) . . . Leaded type (manufactured by Sanko Kinzoku Co., Ltd.)
Interconnector (2) . . . Lead-free type (manufactured by Sanko Kinzoku Co., Ltd.)

2-2. Corrosion Evaluation

(i) Each two interconnectors cut into 8 cm were arranged at equal intervals on the glass on which an encapsulation sheet was superimposed, and an encapsulation sheet and a glass in this order were further superimposed thereon, followed by performing lamination to fabricate a module sample. This sample was subjected to 1000-hour aging under an atmosphere of 85° C.·90% RH, and the corrosion state of the interconnectors was visually observed.

(ii) As in Section (i) above, each two silver-plated steel plates (0.5 mm thickness×10 cm length×2 cm width, manufactured by Test Piece Manufacturing Co., Ltd.) were arranged at equal intervals on the glass on which an encapsulation sheet was superimposed, and an encapsulation sheet and a glass in this order were further superimposed thereon, followed by performing lamination to fabricate a module sample. This sample was subjected to 1000-hour aging under an atmosphere of 85° C.·90% RH, and the corrosion state of silver plating was visually observed.

In order to accelerate corrosion, this test was configured with the interposition of a test piece (interconnector or silver-plated steel plate) between two encapsulation sheets.

(2) Corrosion Test-2

4-1. Interconnector
Interconnector (1) . . . Leaded type (manufactured by Sanko Kinzoku Co., Ltd.)
Interconnector (2) . . . Lead-free type (manufactured by Sanko Kinzoku Co., Ltd.)

4-2. Corrosion Evaluation

(i) An encapsulation sheet was placed on a silicone-treated PET film (silicone-treated polyethylene terephthalate film. Hereinafter the same as above), each two interconnectors cut into 8 cm were arranged thereon at equal intervals, and an encapsulation sheet was further placed thereon, followed by performing lamination to fabricate a module sample. This sample was subjected to 1000-hour aging under an atmosphere of 85° C.·90% RH, and the corrosion state of the interconnectors was visually observed.

As the silicone-treated PET film, CERAPEEL MDA(S) (manufactured by Toray Advanced Film Co., Ltd.) was used.

(ii) As in Section (i) above, an encapsulation sheet was placed on a silicone-treated PET film, one silver-plated steel plate (0.5 mm thickness×10cm length×2 cm width, manufactured by Test Piece Manufacturing Co., Ltd.) was placed thereon, and an encapsulation sheet was further placed thereon, followed by performing lamination to fabricate a module sample. This sample was subjected to 1000- and 2000-hour aging under an atmosphere of 85° C.·90% RH, and the corrosion state of silver plating was visually observed.

(iii) As in Section (i) above, an encapsulation sheet was placed on a silicone-treated PET film, one copper substrate (0.5 mm thickness×10cm length×2cm width, manufactured by Test Piece Manufacturing Co., Ltd.) was placed thereon, and an encapsulation sheet was further placed thereon, followed by performing lamination to fabricate a module sample. This sample was subjected to 1000-hour aging under an atmosphere of 85° C.·90% RH, and the corrosion state of the copper substrate was visually observed. In order to accelerate corrosion, this test was configured with the interposition of a test piece (interconnector or silver-plated steel plate) between two encapsulation sheets.

### Example 1

### Preparation of Silane-Modified Polyethylene (1)

2.5 parts by mass of (B-1), and 1 part by mass of (C-7) were impregnated in advance in 100 parts by mass of (A-1), and melt-blended at a processing temperature of 180° C. (40 mmφ single-screw extruder, L/D=28, frontal Dulmadge type screw, 40 min⁻¹) to prepare silane-modified polyethylene (1). The amount of polymerized silicon in the silane-modified polyethylene was 4600 ppm.

### Preparation of Encapsulation Sheet

Next, 70 parts by mass of (A-2), 20 parts by mass of silane-modified polyethylene (1), and 10 parts by mass of (D-3) were dry blended, and an encapsulation sheet having a thickness of 0.4 mm was prepared, using a 40 mmφ single-screw T-die molding machine at a resin temperature of 160° C. The amount of polymerized silicon in the encapsulation sheet was 900 ppm. Using this encapsulation sheet, the evaluation of Glass adhesion, Corrosion test-1 was carried out. The evaluation results are given in Table 1 below.

Further, the amount of polymerized silicon was measured by heating and burning the silane-modified polyethylene or encapsulation sheet to ashes, melting the ashes in alkali, and dissolving the ashes in pure water, followed by adjustment to a constant volume and quantitative analysis via ICP emission spectrometry (high-frequency plasma emission spectrometer: ICPS8100, manufactured by Shimadzu Corporation).

### Comparative Example 1

70 parts by mass of (A-2), 20 parts by mass of silane-modified polyethylene (1), and 10 parts by mass of (D-1) were dry blended, and an encapsulation sheet having a thickness of 0.4 mm was prepared, using a 40 mmφ single-screw T-die molding machine at a resin temperature of 160° C. Using this encapsulation sheet, the evaluation of Glass adhesion, Corrosion test-1 was carried out. The evaluation results are given in Table 1 below.

### Comparative Example 2

70 parts by mass of (A-2), 20 parts by mass of silane-modified polyethylene (1), and 10 parts by mass of (D-2) were dry blended, and an encapsulation sheet having a thickness of 0.4 mm was prepared, using a 40 mmφ single-screw T-die molding machine at a resin temperature of 160° C. Using this encapsulation sheet, the evaluation of Glass adhesion, Corrosion test-1 was carried out. The evaluation results are given in Table 1 below.

### Comparative Example 3

100 parts by mass of (A-3), 0.5 parts by mass of (B-2), 0.96 parts by mass of (C-8), 0.24 parts by mass of (C-9), 0.3 parts by mass of (C-5), 0.1 parts by mass of (C-6), and 0.03 parts by mass of (C-1-1) were dry blended, and an encapsulation sheet having a thickness of 0.4 mm was prepared, using a 40 mmφ single-screw T-die molding machine at a resin temperature of 90° C. Using this encapsulation sheet, the evaluation of Glass adhesion, Corrosion test-1 was carried out. The evaluation results are given in Table 1 below.

TABLE 1

| | Amount of | | | | Glass adhesion | |
|---|---|---|---|---|---|---|
| | metal | Status of corrosion | | | [N/15 mm] | |
| | deactivator | | Interconnector | Interconnector | | After |
| | (ppm) | Ag substrate | (1) | (2) | Initial | 1000 hr |
| Example 1 | 1000 | None | None | None | 57 | 60 |
| Comparative | 0 | Yes | Yes | Yes | 55 | 58 |
| Example 1 | | (yellowing) | (yellowing) | (darkening) | | |
| Comparative | 0 | Yes | None | Yes | 58 | 55 |
| Example 2 | | (yellowing) | | (darkening) | | |
| Comparative | 0 | None | None | Yes | 25 | 18 |
| Example 3 | | | | (darkening) | | |

In Table 1, the “Amount of metal deactivator (ppm)” represents the content (by mass) of a metal deactivator in the encapsulation sheet.

As shown in Table 1, Example 1 exhibited no corrosion and excellent adhesiveness with glass. On the other hand, Comparative Examples 1 to 3 failed to obtain desired corrosion resistance, due to the occurrence of corrosion. Further, Comparative Example 3 also exhibited poor adhesiveness to glass.

### Example 2

### Preparation of Silane-Modified Polyethylene (2)

2.5 parts by mass of (B-1) and 1 part by mass of (C-7) were impregnated in advance in 100 parts by mass of (A-4), and melt-blended at a processing temperature of 200° C. (40 mmφ single-screw extruder, L/D=28, frontal Dulmadge type screw, 50 min⁻¹) to prepare silane-modified polyethylene (2).

### Preparation of Encapsulation Sheet

Next, 63.5 parts by mass of (A-4), 20 parts by mass of silane-modified polyethylene (2), 10 parts by mass of (D-4), 4 parts by mass of (D-5), and 2.5 parts by mass of (D-6) were dry blended, and an encapsulation sheet having a thickness of 0.4mm was prepared, using a 40 mmφ single-screw T-die molding machine at a resin temperature of 160° C. Using this encapsulation sheet, the evaluation of Corrosion test-2 was carried out. The evaluation results are given in Table 2 below.

### Example 3

61 parts by mass of (A-4), 20 parts by mass of silane-modified polyethylene (2), 10 parts by mass of (D-4), 4 parts by mass of (D-5), and 5 parts by mass of (D-6) were dry blended, and an encapsulation sheet having a thickness of 0.4 mm was prepared, using a 40 mmφ single-screw T-die molding machine at a resin temperature of 160° C. Using this encapsulation sheet, the evaluation of Corrosion test-2 was carried out. The evaluation results are given in Table 2 below.

### Example 4

56 parts by mass of (A-4), 20 parts by mass of silane-modified polyethylene (2), 10 parts by mass of (D-4), 4 parts by mass of (D-5), and 15 parts by mass of (D-6) were dry blended, and an encapsulation sheet having a thickness of 0.4 mm was prepared, using a 40 mmφ single-screw T-die molding machine at a resin temperature of 160° C. Using this encapsulation sheet, the evaluation of Corrosion test-2 was carried out. The evaluation results are given in Table 2 below.

### Example 5

61 parts by mass of (A-4), 20 parts by mass of silane-modified polyethylene (2), 10 parts by mass of (D-4), 4 parts by mass of (D-5), and 5 parts by mass of (D-7) were dry blended, and an encapsulation sheet having a thickness of 0.4 mm was prepared, using a 40 mmφ single-screw T-die molding machine at a resin temperature of 160° C. Using this encapsulation sheet, the evaluation of Corrosion test-2 was carried out. The evaluation results are given in Table 2 below.

### Example 6

61 parts by mass of (A-4), 20 parts by mass of silane-modified polyethylene (2), 10 parts by mass of (D-4), 4 parts by mass of (D-5), and 5 parts by mass of (D-8) were dry blended, and an encapsulation sheet having a thickness of 0.4 mm was prepared, using a 40 mmφ single-screw T-die molding machine at a resin temperature of 160° C. Using this encapsulation sheet, the evaluation of Corrosion test-2 was carried out. The evaluation results are given in Table 2 below.

### Example 7

61 parts by mass of (A-4), 20 parts by mass of silane-modified polyethylene (2), 10 parts by mass of (D-4), 4 parts by mass of (D-5), and 5 parts by mass of (D-9) were dry blended, and an encapsulation sheet having a thickness of 0.4 mm was prepared, using a 40 mmφ single-screw T-die molding machine at a resin temperature of 160° C. Using this encapsulation sheet, the evaluation of Corrosion test-2 was carried out. The evaluation results are given in Table 2 below.

### Comparative Example 4

66 parts by mass of (A-4), 20 parts by mass of silane-modified polyethylene (2), 10 parts by mass of (D-4), and 4 parts by mass of (D-5) were dry blended, and an encapsulation sheet having a thickness of 0.4 mm was prepared, using a 40 mmφ single-screw T-die molding machine at a resin temperature of 160° C. Using this encapsulation sheet, the evaluation of Corrosion test-2 was carried out. The evaluation results are given in Table 2 below.

TABLE 2

| | | Status of corrosion | | | | |
|---|---|---|---|---|---|---|
| | Amount of | Ag | Ag | Cu | Interconnector | Interconnector |
| | metal | substrate | substrate | substrate | (1) | (2) |
| | deactivator | After | After | After | After | After |
| | (ppm) | 1000 hr | 2000 hr | 1000 hr | 1000 hr | 1000 hr |
| Example 2 | 500 | None | Black spots | Rusted | None | None |
| | | | observed | | | |
| Example 3 | 1000 | None | None | Rust-free | None | None |
| Example 4 | 3000 | None | None | Rust-free | None | None |
| Example 5 | 1000 | None | None | Rust-free | None | None |
| Example 6 | 1000 | None | None | Rust-free | None | None |
| Example 7 | 1000 | None | None | Rust-free | None | None |
| Comparative | 0 | Yes | — | Heavily | None | Yes |
| Example 4 | | (yellowing) | | rusted | | (yellowing) |

In Table 2, the “Amount of metal deactivator (ppm)” represents the content (by mass) of a metal deactivator in the encapsulation sheet.

As shown in Table 2, Examples 2 to 7 exhibited inhibition of corrosion. Further, when glass adhesion for the encapsulation sheets of Examples 2 to 7 was examined in the same manner as in Example 1, the encapsulation sheets of Examples 2 to 7 also exhibited excellent adhesiveness with glass. On the other hand, Comparative Example 4 failed to obtain desired corrosion resistance, due to the occurrence of corrosion.

The entire disclosure of Japanese Patent Application No. 2009-260131 is incorporated herein into this specification by reference.

All documents, patent applications and technical specifications recited in this specification are incorporated herein by reference in this specification to the same extent as if each individual publication, patent applications and technical standard was specifically and individually indicated to be incorporated by reference.

1. An amorphous silicon solar cell module, comprising:
a solar cell encapsulant containing a metal deactivator and silane-modified polyethylene; and
a metal material adjacent to the solar cell encapsulant and having at least one selected from copper, a lead-free solder alloy or a silver film.

2. The amorphous silicon solar cell module according to claim 1, wherein the metal deactivator is at least one selected from the group consisting of a hydrazine derivative and a triazole derivative, and the content of the metal deactivator in the solar cell encapsulant is 500 ppm or more.

3. The amorphous silicon solar cell module according to claim 1, wherein the solar cell encapsulant further contains non-modified polyethylene, and a proportion of the silane-modified polyethylene is in a range of from 1% to 80% by mass, in terms of a mass ratio relative to the total mass of a mixture of the silane-modified polyethylene and the non-modified polyethylene.

4. The amorphous silicon solar cell module according to claim 1, wherein the content of silicon (Si) in the solar cell encapsulant is in a range of from 8 ppm to 3500 ppm in terms of an amount of polymerized silicon.

5. The amorphous silicon solar cell module according to claim 1, wherein the polyethylene that forms the silane-modified polyethylene is at least one selected from the group consisting of low density polyethylene, medium density polyethylene, high density polyethylene, very low density polyethylene, ultra-low density polyethylene, and linear low density polyethylene.

6. The amorphous silicon solar cell module according to claim 1, wherein the metal material is at least one of a busbar or an interconnector.

7. The amorphous silicon solar cell module according to claim 1, wherein the solar cell encapsulant contains at least one selected from the group consisting of an antioxidant, an ultraviolet absorber and a light stabilizer.
